(19) United States
(12) Patent Application Publication
(10) Pub. No.: US 2012/0153972 A1
(43) Pub. Date: Jun. 21, 2012

(54) VEHICLE OPENING DEVICE

(75) Inventors: Alfons Stockschlager, Viersen (DE); Klaus Hanndorf, Krefeld (DE); Norbert Heller, Viersen (DE)

(73) Assignee: Henniges Automotive Sealing Systems North America, Inc., Farmington Hills, MI (US)

(21) Appl. No.: 12/279,504

(22) PCT Filed: Feb. 16, 2007
(86) PCT No.: PCT/IB2007/000388

§ 371 Date: May 18, 2009

(30) Foreign Application Priority Data
Feb. 17, 2006 (GB) 0603247.8

(51) Int. Cl. G01R 27/26

(52) U.S. Cl. 324/672

(57) ABSTRACT

A sensing arrangement for sensing a body part in a vehicle opening is described. The arrangement includes a flexible sealing member with two separate electrically conductive members. The two electrically conductive members are interconnected by an electrical oscillator which generates an electric field in the vehicle opening. The arrangement also includes detecting circuitry for detecting a change in the capacitance of the electric field when the body part is in the vicinity of the opening, and for detecting electrical continuity of the first and second electrically conductive members.

This invention relates to a sensing arrangement for sensing a body part in an opening, such as a vehicle window opening.

More particularly, the invention relates to verifying the operation of the sensing assembly.

US 2004/0172879 discloses an object sensing arrangement with two electrodes in which the electrodes are connected by a control resistor, and the system integrity is tested by applying a testing voltage to the electrodes. The control resistor does not perform any other function as the sensing assembly operates.

It is an object of the invention to provide an object sensing arrangement in which the electrical component used to connect the sensors of the arrangement and thereby ensure system continuity is also used to generate the electric field which is used in detecting body parts in vehicle openings.

According to the invention there is provided a sensing arrangement for sensing a body part in a vehicle opening, the sensing arrangement comprising:

a flexible sealing member adapted to be positioned adjacent to said opening; a first electrically conductive member within said flexible sealing member; a second electrically conductive member within said flexible sealing member, separate from said first electrically conductive member; an oscillator for supplying an oscillating signal to said first and second electrically conductive members to generate an electric field in the vicinity of the vehicle opening, and detection circuitry for detecting a change of capacitance of said first and second electrically conductive members due to presence of a said body part in said electric field, wherein at least part of said oscillator electrically interconnects the first and second electrically conductive members enabling electrical continuity of the first and second electrically conductive members to be tested.

Embodiments of the invention will now be described, by way of example only, with reference to the accompanying diagrammatic drawings in which:

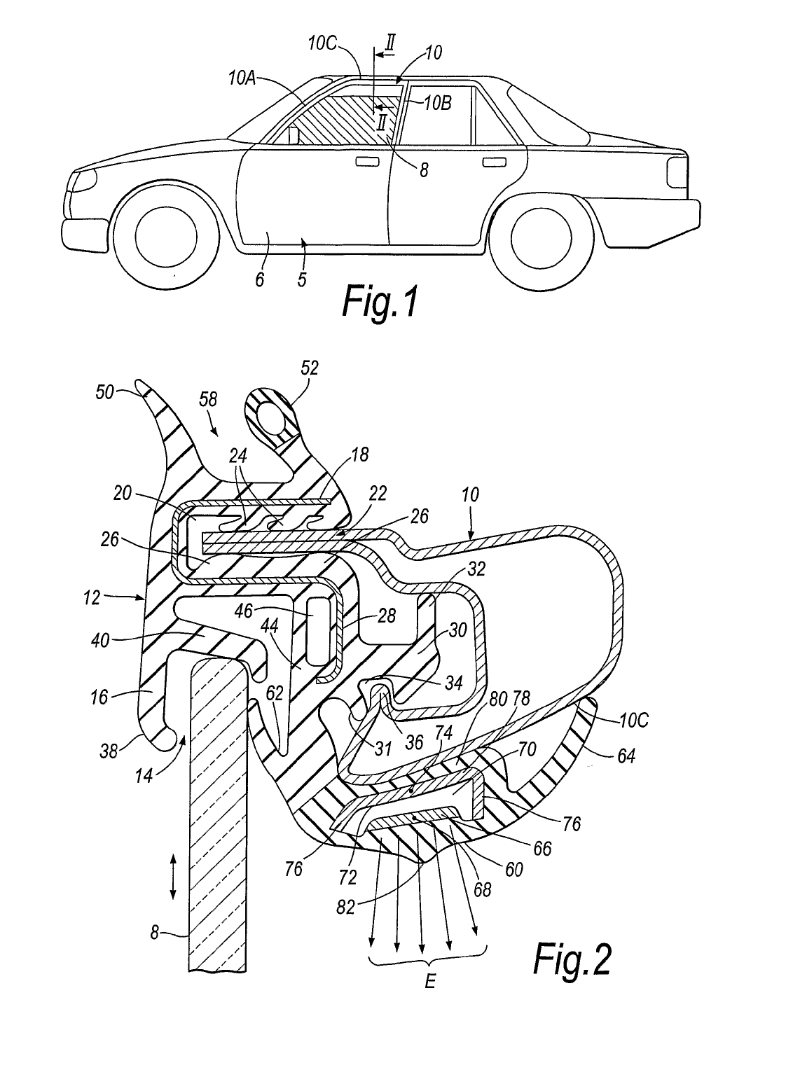

FIG. 1 is a diagrammatic side elevation of a motor vehicle;

FIG. 2 is a cross-sectional view along line II-II of FIG. 1 of the window frame with a sealing and guiding strip showing an arrangement according to the invention;

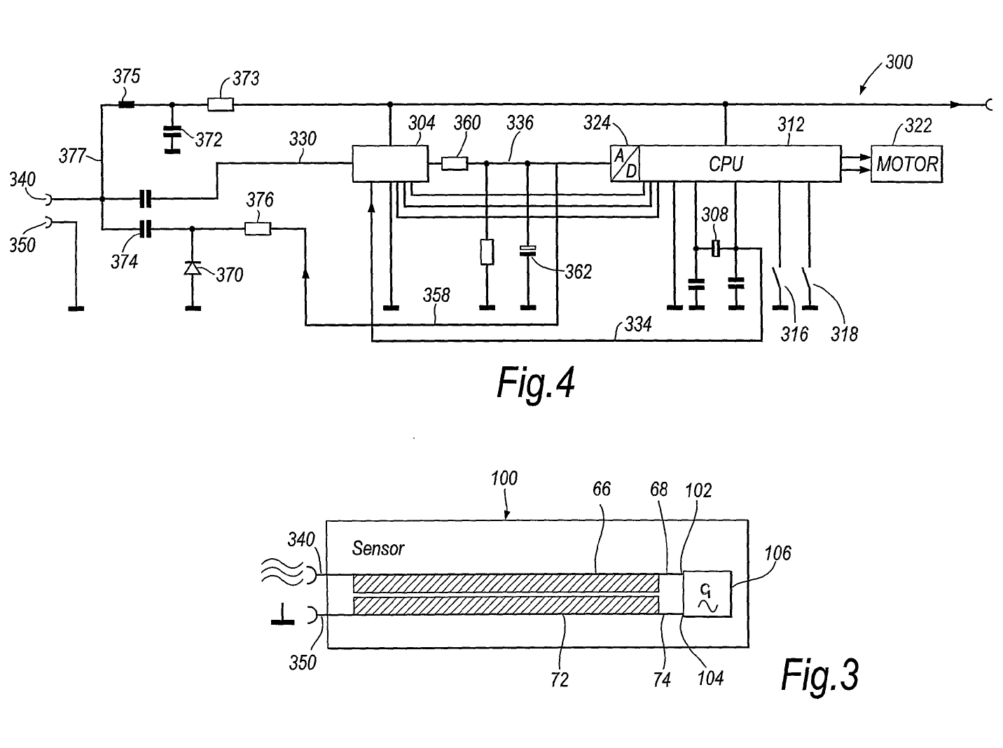

FIG. 3 is a representative view of the connection between the electrically conductive members and the oscillator.

FIG. 4 is a block circuit diagram for the sensing arrangement shown in FIGS. 2 and 3.

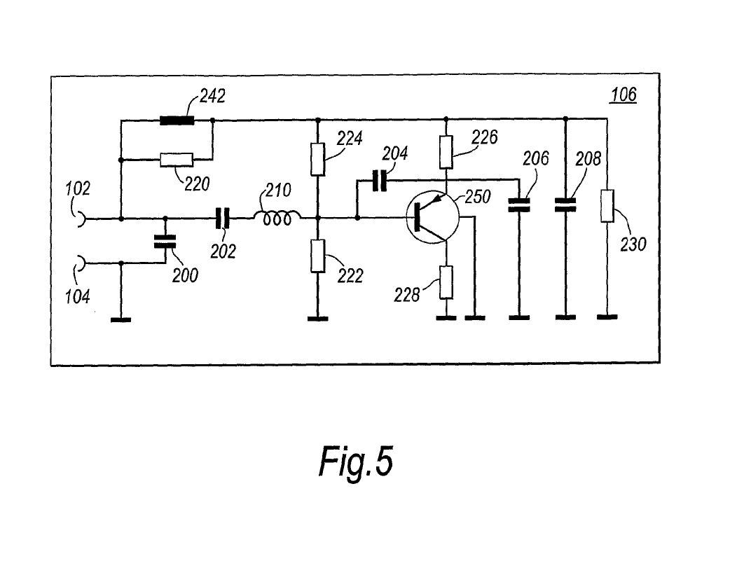

FIG. 5 is a circuit diagram of the oscillator G in FIG. 3.

In the drawings, like elements are generally designated with the same reference numeral.

FIG. 1 shows a motor vehicle 5 having a front door 6 with a power-driven window 8 which is shown cross-hatched for clarity. The power-driven window 8 is raised and lowered by means of a suitable motor, normally an electric motor, under the control of switches positioned within the vehicle for use by the driver or passenger. All or some of the other side windows in the vehicle may also be power-driven.

The window frame 10, forming part of the vehicle door, incorporates a window guide channel 12 one form of which is shown in FIG. 2. The window guide channel comprises extruded plastics or rubber material which incorporates an embedded metal core or carrier 18.

The carrier 18 may take any suitable form. For example, it may comprise a simple channel of metal. The channel could additionally be formed with apertures to increase its flexibility. Instead, the carrier could be made from U-shaped metal elements arranged side-by-side to define the channel and either connected together by short flexible interconnecting links or entirely disconnected from each other. The metal could be steel or aluminum, for example.

Instead, the carrier could be made of metal wire looped to and fro to define the channel.

The carrier 18 is advantageously incorporated into the extruded material by a known cross-head extrusion process.

In this embodiment the carrier 18 is C-shaped, with an extension piece 28 extending down from one of the arms of the C-shaped channel. Between extension piece 28 and sidewall 44 is a hollow chamber 46. Advantageously, metal carrier 18 within the window guide channel 12 where it runs along the top part 10C of the window frame (FIG. 1) is separated from the metal carrier 18 in those parts of the window guide channel 12 fitted to parts 10A and 10B of the window frame.

The extruded material defines a lip 40 projecting outwardly from a sidewall of the channel 12, a lip 62 directed inwardly into the channel from sidewall 44 of the channel and a similar lip 38 on the opposite side of the channel but of shorter extent.

The area 14 between window 8 and lip 38 of channel 12 is glass receiving channel 14.

The window frame 10 (FIG. 1) may take the form of a metal channel which is sized to receive the window guide channel 12 as shown in FIG. 2. When the channel 12 is fitted into position within this frame, lips 24 and 26 (FIG. 2) overlap and grip the outsides of the window frame 10, specifically lips 24 contact panel 22 of window frame 10.

The window guide channel 12 extends around the sides and top of the frame 10. Thus, it extends up that part 10A of the frame alongside the “A” pillar of the vehicle, along the top 10C of the frame and down that part 10B of the frame corresponding to the “B” pillar. Where the window glass 8 slides into and out of the lower part 5A of the door 5, a waist-seal (not shown) is provided on each side of the slot.

The surfaces of the window guide channel 12, and of the waist-seal, which contact the sliding glass are advantageously covered in flock or other suitable material to provide a low-friction and substantially weather-proof surface.

The window guide channel 12 also has a portion 30 which is clipped into window frame 10C and also holds the window guide channel in position. Lips 32 and 31 contact parts of window frame 10C to hold window guide channel 12 in position.

As shown in FIG. 2, window guide channel 12 includes sealing member 52 and sealing lip 50 on the outside of the window frame. Sealing member 52 and sealing lip 50 engage the frame of the door opening when the door 5 is closed, to provide a seal around the edge of the door 5.

Window guide channel 12 also includes flexible seal member 60. This may be formed of the same extruded plastic or rubber material as window guide channel 12 or a different material. It may be formed integrally with window guide channel 12, or as a separate element to be joined to window guide channel 12. Seal member 60 may be joined to window guide channel 12 during the moulding operation which forms window guide channel 12 or they may be joined by applying an adhesive.

The connection between window guide channel 12 and seal member 60 is not an essential feature of the invention. Flexible seal member 60 is located on the underside of window frame 10, inside of the car at a distance from window 8.

Embedded in seal member 60 are an outer electrically conductive member 72 and an inner electrically conductive member 66. The inner and outer electrically conductive members are separated by hollow chamber 70. The outer electrically conductive member 72 includes a wire 74 which is located within and runs the length of outer electrically conductive member 72, and the inner electrically conductive member 66 includes a wire 68 which is located within and runs the length of inner electrically conductive member 66. One end of wire 68 is connected to control circuitry 300 (see FIG. 4) and one end of wire 74 is connected to ground. Of course, these connections may be the other way round. The other ends of wires 74 and 68 are connected together by an oscillator 106, as shown schematically in FIG. 3. A supply voltage Ub is supplied to the oscillator 106 via a low pass filter formed by a capacitor 372 and coil 375 (see FIG. 4), along wire 68 in inner electrically conductive member 66 and via a second low pass filter formed by a coil 242 and a capacitor 208. Coil 242 and capacitor 208 are parts of oscillator 106 (see FIG. 5).

Preferably, the inner and outer electrically conductive members 72, 66 are made of electrically conductive rubber. The remainder of flexible seal member 60 is preferably made from insulating rubber. Preferably wires 74 and 68 are metal wires.

In this embodiment of the invention outer electrically conductive member 72 has a main body portion 78 and side portions 76 which extend away from main body portion 78 towards the inner electrically conductive member 66. The outer electrically conductive member 72 is thus substantially channel-shaped and the inner electrically conductive member 66 is located on the opposite side of hollow chamber 70 within, and extending lengthwise of, the channel defined by the outer electrically conductive member 72. Other arrangements for the inner and outer electrically conductive members may be contemplated and the invention is not limited to electrically conductive members with the shapes as described above.

It is understood that the extruded plastic or rubber material of flexible seal member 60 electrically insulates the inner and outer electrically conductive members 66 and 72 from the vehicle bodywork.

Flexible seal member 60 also has seal region 80 located between the main body portion 78 and window frame 10C. Seal region 80 contacts window frame 10C.

Extending away from seal member 60, on the opposite side of the seal member 60 to window 8 is lip seal 64 which engages with window frame 10C.

Seal member 60 also includes protrusion 82, located on the underside of flexible seal member 60 below inner electrically conductive member 66. The protrusion 82 is separated from inner electrically conductive member 66 by a part of the body of flexible seal member 60.

In the usual way, when a driver or passenger of the vehicle wishes to raise or lower a window they operate an appropriate switch to energise the motor, and the window glass moves either up or down (as desired) within the guide channel 12.

The system now to be described is for sensing a body part (e.g. a hand) which may have been placed within a gap between the window glass 8 and the window frame 10. The system will detect such an obstruction when it comes within a predetermined distance of flexible seal member 60. In a preferred embodiment the motor driving the window glass will stop and/or reverse the window movement to prevent the body part from becoming trapped (and possible injured) in the region between the top of the window glass 8 and the window frame 10C.

As mentioned above wire 68 extends through the length of inner electrically conductive member 66. One end of wire 68 is connected to a line 330 in circuit 300 (see FIG. 4) by connection 340. The opposite end of wire 68 is connected to one side of the oscillator 106 by connection 102. The other side of oscillator 106 is connected by connection 104 to one end of wire 74. As mentioned previously wire 74 runs through outer electrically conductive member 72. The other end of wire 74 is connected by connection 350 to ground.

FIG. 5 shows the various electronic components making up oscillator 106. As can be seen, the oscillator is made up of capacitors 200, 202, 204, 206 and 208, resistors 220, 222, 224, 226, 228 and 230, coils 240, 242 and a transistor 250. The construction and operation of the oscillator is well known and will not be described in detail here. As described previously capacitor 208 and coil 242 together form a low pass filter for supply voltage Ub of oscillator 106. The resistor 220 acts as damper for coil 242.

Preferably, the electronic circuitry making up the oscillator 106 is encapsulated by overmoulding. This circuitry can be overmoulded separately from the seal member 60, or can be overmoulded by extending the seal member 60 to cover the circuitry.

When the wire 68 in inner electrically conductive member 66 is energised by oscillator 106 an electric field is radiated and is present within the vicinity of the window frame 10. The relationship between the arrangement of the two electrically conductive members 66, 72 in this embodiment is such that electric field lines are concentrated in the vicinity of the window opening. This is because the inner and outer electrically conductive members 66, 72 are significantly differently shaped. More specifically, in this embodiment, side portions 76 of the outer electrically conductive member 72 are directed towards the inner electrically conductive member 66 to define a channel, and the inner electrically conductive member 66, which is relatively flat, extends lengthwise of the channel, in this example wholly within the channel.

Electric field lines generated by this arrangement are represented by arrows E in FIG. 2. As depicted in that Figure, the field lines are concentrated in the vicinity of the window opening; elsewhere, for example outside the window opening or within the interior of the vehicle, the field lines are much less dense.

The concentration of field lines in the vicinity of the window opening gives the sensing assembly greater sensitivity to the presence of a body part such as a hand within the opening.

FIG. 4 shows a detection circuit 300 for energising motor 322 for raising or lowering the window glass 8.

Motor 322 for driving window glass 8 up and down is connected to micro controller 312 in the circuit 300. Switches 316 and 318 for moving the window up and down respectively are also connected to micro controller 312. Micro controller 312 also includes A/D converter 324.

Detection circuit 300 has a first oscillator 308, which is quartz stabilised and has an output frequency (in this example) of 4 MHz. The output of oscillator 308 passes on line 334 to phase detector 304. Typically, the quartz oscillator 308 and the phase detector 304 are integral components of an electrical chip, such as a Motorola MC145155-2 chip (Motorola CMOS application specific digital analogue integrated circuits 5-53, MC145151-2 Series, page 9).

The output frequency of oscillator 106 is also received along line 330 at phase detector 304. The output frequency of oscillator 308 is compared with output frequency of oscillator 106 in the phase detector 304. As a result of the comparison a control voltage Ur for oscillator 106 is output from the phase detector 304 along line 358. Phase detector 304 includes a divider (not shown) set by micro-controller 312 so that the initial control voltage output for the phase detector 304 is 1 volt.

The initial value of control voltage Ur is also supplied to micro-controller 312 over line 336 where it is stored as a reference value for the control voltage.

The control voltage Ur output from phase detector 304 passes along line 358 to the oscillator 106 via the junction of a resistor 360 and a capacitor 362, acting as a low pass filter.

A variable capacitance device in the form of a varactor 370 is connected to line 358 at the junction of resistor 376 and capacitor 374. This varactor 370 is used to tune the output frequency of oscillator 106 in accordance with the control voltage Ur. The output frequency of oscillator 106 depends on the capacitance of the capacitor formed by the two electrically conductive members 66, 72 and the capacitance of varactor 370.

It will be apparent that oscillator 106 and varactor 370 operate as a voltage controlled oscillator (VCO), responsive to the control voltage Ur.

It will also be apparent that phase detector 304 and the voltage controlled oscillator circuitry form a Phase Locked Loop (PLL). The control voltage Ur is supplied to the varactor 370 by the phase detector 304 via a loop filter (low pass filter) formed by resistor 360 and capacitor 362 to tune the oscillator 106.

When the window is open, closing switch 316 will cause the window to be raised automatically by motor 322. During the movement of the window upwards, the instantaneous frequency of oscillator 106 is continually detected at phase detector 304 and compared with reference output from quartz stabilised oscillator 308. The control voltage Ur resulting from the comparison is output to micro-controller 312 along line 336 to be compared with the stored reference value of the control voltage.

If the difference between the instantaneous control voltage Ur and the stored reference value is below a certain preset threshold then the window will continue to move upwards. The threshold is set to be dependent on the position of the window in the window opening and is such that the window will close, even if the window is wet, when there are no obstacles with high dielectric constant within the vicinity of the electric field in the opening.

If an obstacle with a relatively high dielectric constant e.g. a human body part is within the vicinity of the electric field in the window opening, this will cause a change in capacitance of the capacitor formed by the outer and inner electrically conductive members.

This change in capacitance will lead to a change in frequency of oscillator 106. The altered frequency is received along line 330 at phase detector 304 where it is compared with the reference frequency from quartz oscillator 308.

The control voltage Ur resulting from the comparison is output to micro-controller 312 and the value of control voltage Ur is compared with the stored reference value. If the difference between the two voltage values exceeds the same preset threshold, this indicates that the output frequency of oscillator 106 has changed sufficiently to indicate the presence of a body part in the vicinity of the electric field in the window opening. In this case, micro-controller 312 will stop and preferable reverse the window to prevent damage to the body part in the opening.

The system is set so that the rising window is stopped before the hand or other body part actually makes contact with the top 10C of the window frame (a non-contact mode) or the flexible seal member 60. It can also be set so that the window stops when the hand or other body part is in actual contact with the top 10C of the window frame 10 but before the rising window applies more than a predetermined and non-injurious force to the hand or other body part (e.g. 100 N).

The rising window glass on its own (that is, when no human hand or other body part is present in the gap between the glass and the top 10C of the window frame) does not of itself significantly affect the output of the oscillator 106. This is because the dielectric constant of the window glass is many times less than that of a human hand or other body part.

The system can also be adapted for frameless windows. In this case, there is no separate window frame. The rising and lowering window glass slides with respect to a seal or channel carried by the frame on the vehicle body within which the door is located. This channel or seal (such as a door seal) will normally also incorporate inner and outer electrically conductive members 66, 72 which can thus be connected to receive the output of the oscillator 106 in the manner already explained.

Environmental changes e.g. rainfall may also cause a small change in the capacitance of the capacitor formed by inner and outer electrically conductive members 66, 72. In this case, the small change in capacitance will cause a change in frequency of oscillator 106 which is detected by phase detector 304. As described above, phase detector 304 performs a frequency comparison and outputs an instantaneous control voltage Ur. As described above, a comparison of the value of the instantaneous control voltage and the stored value is performed in the micro-controller 312. The result of the comparison will be below the threshold and movement of the window will not be stopped or disabled as a result of the environmental conditions. The instantaneous control voltage Ur will also be provided to oscillator 106 along line 358 and will tend to compensate the change in capacitance by appropriately adjusting the frequency of the oscillator 106.

The connection of oscillator 106 between inner and outer electrically conductive members 66, 72, enables the continuity of the electrically conductive members to be tested.

As described previously, supply voltage Ub is supplied to oscillator 106 via inner electrically conductive member 66. Oscillator 106 is connected to ground 350 via outer electrically conductive member 72. With this arrangement, a lack of electrical continuity of inner and/or outer electrically conductive members 66, 72 will interrupt or change the provision of supply voltage Ub to oscillator 106. Such lack of continuity may be created for example by a break or defect in inner and/or outer electrically conductive members 66, 72, including wires 74 and 68 which are part of said inner 66 and outer electrically conductive members 72.

The lack of supply voltage Ub at oscillator 106 due to a lack of electrical continuity will cause oscillator 106 to stop functioning, and so the electric field in the window opening will not be generated. If no field is generated, then no frequency will be detected from oscillator 106 at phase detector 304. The comparison in the phase detector 304 will be between the reference frequency and the nil frequency of oscillator 106. The result of the comparison is output from phase detector 304 as an instantaneous control voltage Ur to micro-controller 312. Due to the lack of continuity this control voltage Ur exceeds a maximum threshold value. The micro-controller 312 recognises that Ur has exceeded the threshold (for example by comparing the value of Ur with the stored reference value) and this indicates that there is a lack of electrical continuity in the inner and outer electrically conductive members.

Once the micro-controller has determined the lack of continuity it will disable the motor driving the window glass, and/or generate a warning signal.

As will now be briefly described, the sensing arrangement can also operate in a contact mode, for detecting an object in the opening which contacts flexible seal member 60.

In the system of FIG. 2, protrusion 82 is located on the underside of flexible seal member 60 such that any body part on the rising edge of window glass 8 will eventually contact protrusion 82 as the window glass rises to its closed position. Contact between a body part and protrusion 82 will cause deformation of flexible seal member 60 and inner electrically conductive member 66 will be moved towards the outer electrically conductive member 72. This movement of inner conductive member 66 will cause a change in capacitance of the capacitor defined by the two electrically conductive members 66 and 72 when they are energised by oscillator 106. Like the non-contact detection mode previously described, this change in capacitance will produce a change in the frequency detected on line 330 to phase detector 304 which will lead to a change of control voltage Ur. Again, this change in control voltage will be detected by the micro-controller 312 and will cause the motor 322 to be de-energised as described above, thereby immediately stopping the rising window glass.

Also, it is possible that movement of inner electrically conductive member 66 may be so great, that it moves through the hollow chamber 70 and physically contacts outer electrically conductive member 72. In this case, there will be electrical contact between the two electrically conductive members 66 and 72, and when they are energised this will cause a short circuit. This short circuit causes the supply voltage for oscillator 106 to be less than 0.5V, and no high frequency electric field will be generated by the oscillator 106. This lack of field is detected as described above with respect to the continuity testing by the detection circuitry 300, and will cause motor 322 to be de-energised as described above, thereby immediately stopping the rising glass, if for some reason it has not been stopped already.

1. A sensing arrangement for sensing a body part in a vehicle opening, the sensing arrangement comprising:
(a) a flexible sealing member adapted to be positioned adjacent to the opening;
(b) a first electrically conductive member within the flexible sealing member;
(c) a second electrically conductive member within the flexible sealing member, separate from the first electrically conductive member;
(d) an oscillator for supplying an oscillating signal to the first and second electrically conductive members to generate an electric field in the vicinity of the vehicle opening, and
(e) detection circuitry for detecting a change of capacitance of the first and second electrically conductive members due to presence of a the body part in the electric field, wherein at least part of the oscillator electrically interconnects the first and second electrically conductive members enabling electrical continuity of the first and second electrically conductive members to be tested.

2. The sensing arrangement according to claim 1, wherein the oscillator includes a supply voltage and a control voltage and operates as a voltage controlled oscillator and the detection circuitry includes a phase detector for comparing an output frequency of the oscillator with a reference frequency to generate the control voltage for the oscillator and processing means for detecting one of a change and an interruption of the supply voltage caused by a change of electrical continuity of the first and second electrically conductive members.

3. The sensing arrangement according to claim 2 wherein the processing means includes means for comparing a value of the control voltage with the reference value to detect the one of the change and the interruption and a change of capacitance.

4. The sensing arrangement according to claim 2 wherein the oscillator and the phase detector form a phase locked loop and the control voltage is supplied by the phase detector to a variable capacitance means via a low pass filter.

5. The sensing arrangement according to claim 4 wherein the variable capacitance means is for tuning tunes the oscillator in response to the control voltage.

6. The sensing arrangement according to claim 5 wherein the variable capacitance means is a varactor.

7. The sensing arrangement according to claim 1 wherein the first and second electrically conductive members are differently shaped to concentrate the electric field in the vicinity of the opening.

8. The sensing arrangement according to claim 1 wherein the first and second electrically conductive members are made of electrically conductive rubber.

9. The sensing arrangement according to claim 1 wherein each of the first and second electrically conductive members includes an embedded electrical conductor.

10. The sensing arrangement according to claim 9 wherein the electrical conductor is a wire.

11. The sensing arrangement according to claim 1 wherein the flexible sealing member includes one of an electrically insulating rubber and an electrically insulating plastic.

12. The sensing arrangement according to claim 1 wherein the first and second electrically conductive members are separated by a hollow chamber.

13. The sensing arrangement according to claim 1 wherein the vehicle opening is a window opening including a motor driven window glass and the detection circuitry is arranged to at least one of halt and reverse upward movement of the window glass in response to at least one of a detected change of capacitance and a change of electrical continuity.

14. The sensing arrangement according to claim 1, further comprising one of a sealing strip and a guiding strip.

15. (canceled)

16. (canceled)

17. A sensing arrangement for sensing a body part in a vehicle opening, the sensing arrangement comprising:
(a) a flexible sealing member adapted to be positioned adjacent to the opening;
(b) a first electrically conductive member within the flexible sealing member;
(c) a second electrically conductive member within the flexible sealing member, the second electrically conductive member being spaced from the first electrically conductive member;
(d) an oscillator for supplying an oscillating signal to the first and second electrically conductive members to generate an electric field in the vicinity of the vehicle opening, a first side of the oscillator being connected to the first electrically conductive member and a second side of the oscillator being connected to second electrically conductive member, the connection of the oscillator to the first and the second electrically conductive members enabling testing of an electrical continuity of the first and the second electrically conductive members; and
(e) detection circuitry for detecting a change of capacitance of the first and second electrically conductive members due to presence of a the body part in the electric field.

18. The sensing arrangement according to claim 17 wherein the lack of electrical continuity of the first and the second electrically conductive members changes a supply voltage to the oscillator.
